(19) United States
(12) Patent Application Publication
(10) Pub. No.: US 2010/0064198 A1
(43) Pub. Date: Mar. 11, 2010

(54) STORED DATA PROCESSING APPARATUS, STORAGE APPARATUS, MEDIUM STORING STORED DATA PROCESSING PROGRAM, AND STORED DATA PROCESSING METHOD

(75) Inventors: Osamu Yoshida, Kawasaki (JP); Shigenori Yanagi, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/511,801

(22) Filed: Jul. 29, 2009

(30) Foreign Application Priority Data
Sep. 5, 2008 (JP) 2008-227800

(51) Int. Cl. H03M 13/00; G11C 29/00; G06F 11/08; G06F 11/16

(52) U.S. Cl. 714/755; 714/764; 714/766; 714/E11.03; 714/E11.054

(57) ABSTRACT

A stored data processing apparatus includes: a format controller that adds an error correction code to data written onto a disk medium for each first block; a redundant data generation section that performs calculation for each bit position using data of all the first blocks in a second block and outputs a result of the calculation as calculation data, the second block being constituted by a plurality of the first blocks each including the error correction code added by the format controller and specified as an update target; and an MPU that writes the calculation data output from the redundant data generation section in a third block associated with the second block as the update target.

### CROSS-REFERENCE TO RELATED APPLICATIONS

This application is based upon and claims the benefit of priority of the prior Japanese Patent Application No. 2008-227800, filed on Sep. 5, 2008, the entire contents of which are incorporated herein by reference.

### FIELD

The present invention relates to data correction in a storage apparatus.

### BACKGROUND

The storage capacity of a storage apparatus, especially, disk apparatus has been increasing. For example, a disk apparatus of 1 terabyte or more is now available. Along with the increase in the disk capacity, the degree of damage becomes severe in the case where a read error occurs in a given sector. In particular, in the case where the read error occurs in a given sector corresponding to a location where directory information concerning data management in a disk apparatus has been recorded, enormous numbers of data may be damaged. The seriousness of the damage increases as the capacity of the disk apparatus increases. As a means for avoiding such a trouble in a disk apparatus, a system in which one disk apparatus is configured as part of an array has been available to a large-scale system. In this system, if there exists any disk apparatus that has got a read error, another disk apparatus provided for increasing redundancy is used to recover the data. In order to enhance the resistance of a single disk apparatus against such a read error, a method that adds an ECC (Error Correcting Code) to a sector has been adopted. The ECC is a code for performing error check and data correction for the sector to which the ECC has been added, and the correction capability of the ECC has gradually been increasing.

However, in the case where the data readout operation from the sector at which the read error has occurred does not succeed even when retry is attempted and where data correction using the added ECC has failed, the disk apparatus notifies a higher-level device connected thereto of a read error and ends the readout operation. Further, although the data correction capability itself using the ECC has gradually been increasing as described above, a new data correction method has not been adopted and conventional techniques have continued to be used in recent years. Thus, the correction capability of the ECC lags behind the increase in the storage capability of a single disk apparatus and, therefore, that the risk of data loss in the disk apparatus relatively increases.

As a prior art relating to the present invention, there is known a magnetic disk apparatus that specifies data in which error has occurred so as to correct error that cannot be corrected using the ECC (refer to, e.g., Patent Document 1: Japanese Laid-Open Patent Publication No. 05-109208).

### SUMMARY

A stored data processing apparatus for use in a storage apparatus that performs at least write processing for a storage medium on which data is allocated in units of a first block having a predetermined data length, comprising: an error correction code addition section that adds an error correction code to data written onto the storage medium for each first block; a calculation section that performs calculation for each bit position using data of all the first blocks in a second block and outputs a result of the calculation as calculation data, the second block being constituted by a plurality of the first blocks each including the error correction code added by the error correction code addition section and specified as an update target; and a write section that writes the calculation data output from the calculation section in a third block associated with the second block as the update target.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a block diagram illustrating a higher-level device and an HDD according to an embodiment of the present invention;

FIG. 2 is a block diagram illustrating a configuration of the HDD according to the present embodiment;

FIG. 3 is a block diagram illustrating a configuration of a format controller;

FIG. 4 is a block diagram illustrating a configuration of a redundant data generation section;

FIG. 5 is a view illustrating an example of sector allocation in the case where a redundant sector is allocated for each track;

FIG. 6 is a view illustrating an example of sector allocation in the case where a redundant sector is allocated for each predetermined number of sectors;

FIG. 7 is a view illustrating an example of sector allocation in the case where a redundant sector is allocated for each predetermined number of sectors;

FIG. 8 is a flowchart illustrating operation of redundant data update processing;

FIG. 9 is a flowchart illustrating operation of redundant data generation processing;

FIG. 10 is a view illustrating a data path in the redundant data generation processing;

FIG. 11 is a view illustrating a data path in the redundant data generation processing;

FIG. 12 is a view illustrating a data path in the redundant data generation processing;

FIG. 13 is a view illustrating a data path in the redundant data generation processing;

FIG. 14 is a flowchart illustrating operation of error data recovery processing;

FIG. 15 is a view illustrating a data path in the error data recovery processing;

FIG. 16 is a view illustrating a data path in the error data recovery processing;

FIG. 17 is a view illustrating a data path in the error data recovery processing;

FIG. 18 is a view illustrating a data path in the error data recovery processing;

FIG. 19 is a flowchart illustrating operation of the error data recovery processing in the case where only data preceding the error sector is stored in the buffer memory;

FIG. 20 is a view illustrating a data path in the error data recovery processing;

FIG. 21 is a view illustrating a data path in the error data recovery processing;

FIG. 22 is a view illustrating a data path in the error data recovery processing;

FIG. 23 is a flowchart illustrating operation of breakage position specification processing;

FIG. 24 is a view illustrating a data path in the breakage position specification processing;

FIG. 25 is a view illustrating breakage position information; and

FIG. 26 is a view illustrating an example of a computer system to which the present invention can be applied.

### DESCRIPTION OF EMBODIMENT

An embodiment of the present invention will be described with reference to accompanying drawings.

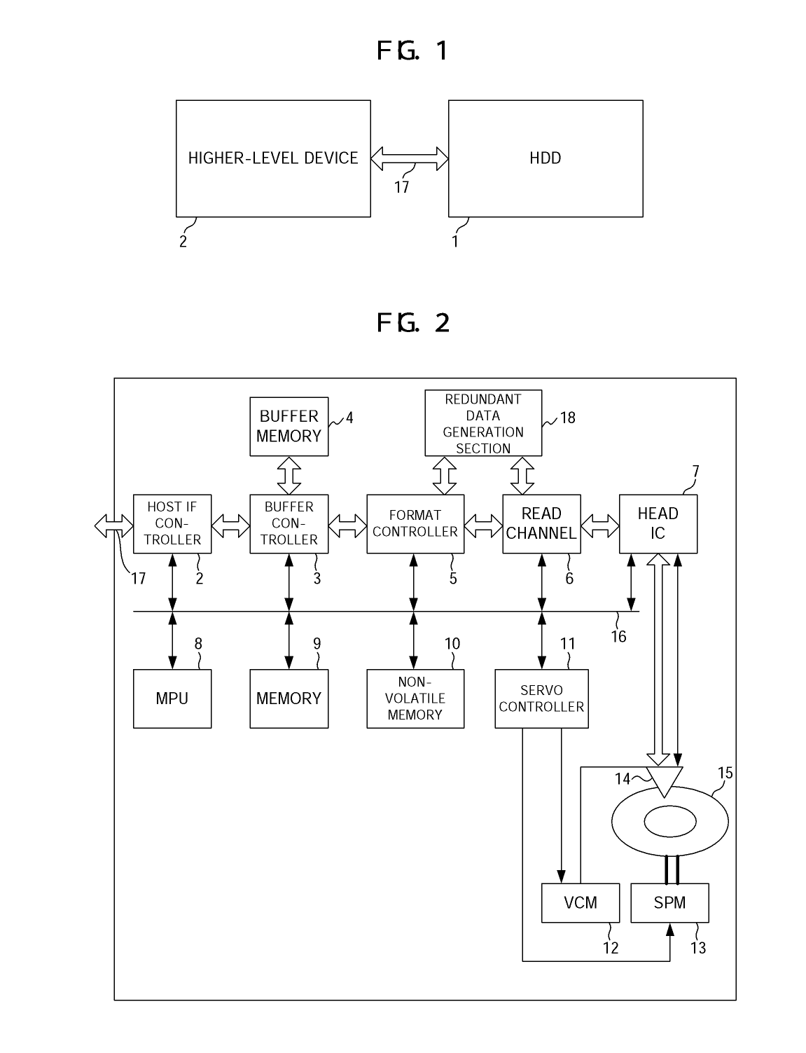

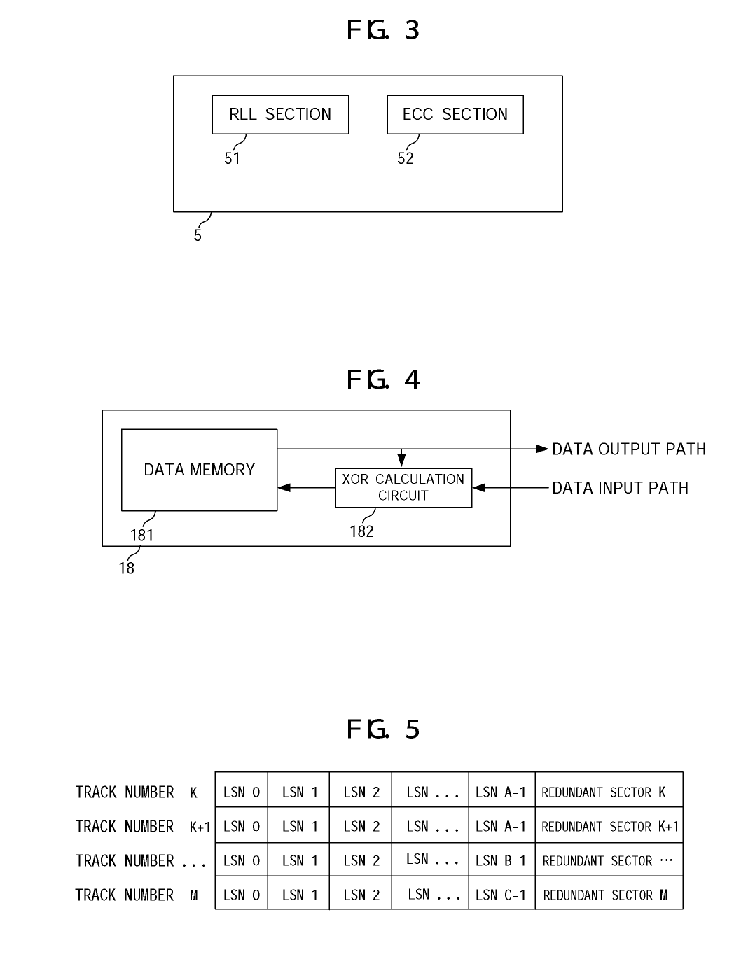

A configuration of an HDD according to the present embodiment will first be described. FIG. 1 is a block diagram illustrating a higher-level device and an HDD according to the present embodiment. FIG. 2 is a block diagram illustrating a configuration of the HDD according to the present embodiment.

As illustrated in FIG. 1, a higher-level device 2 and an HDD 1 are connected to each other via a host IF 17. The higher-level device 2 is, e.g., a personal computer using the HDD 1 as a storage apparatus and issues a command to the HDD 1 in data write/read operation.

As illustrated in FIG. 2, the HDD 1 includes a host IF controller 2, a buffer controller 3, a buffer memory 4, a format controller (correction code addition section) 5, a read channel 6, a head IC 7, an MPU (write section, read section, error position specification section, error position recording section) 8, a memory 9, a non-volatile memory 10, a servo controller 11, a VCM (Voice Coil Motor) 12, an SPM (Spindle Motor) 13, a read/write head 14, a disk medium (storage medium) 15, a common bus 16, a host IF 17, a redundant data generation section (calculating section, error position specification section) 18.

The disk medium 15 stores data. The read/write head 14 writes/reads a signal as data to/from the disk medium 15. The SPM 13 is a motor for rotating the disk medium 15. The VCM 12 is a motor for driving the read/write head 14. The servo controller 11 controls the VCM 12 and SPM 13. The head IC 7 amplifies a signal to be written/read onto or from the disk medium 15 by the read/write head 14. The read channel 6 converts data to be written/read onto or from the disk medium 15 into a signal. The format controller 5 generates a recording format of data to be recorded in the disk medium 15. The buffer memory 4 is a memory for temporarily storing data to be written/read onto or from the disk medium 15. The buffer controller 3 controls the buffer memory 4. The memory 9 is a volatile memory. The non-volatile memory stores a program for controlling the HDD. The host IF 17 is an IF for exchanging data to be recorded in the disk medium 15 and a command between the higher-level device 2 and HDD 1. The MPU 8 executes control and processing in the HDD 1. The redundant data generation section 18 will be described later.

Generally, when data is read out from a disk in the HDD 1 having the configuration described above, the data is read out by the read/write head 14 from the disk medium 15 and sent to the read channel 6 via the head IC 7. The data sent to the read channel 6 is sent, via the format controller 5 and buffer controller 3, to the buffer memory 4 for temporary storage. The data retained in the buffer memory 4 is sent to the higher-level device 2 via the host IF controller 2 and host IF 17. When data is written onto a disk, the data from the higher-level device 2 is sent, via host IF 17, host IF controller 2, and buffer controller 3, to the buffer memory 4 for temporary storage. The data retained in the buffer memory 4 is sent to the read/write head 14 via the format controller 5, read channel 6 and head IC 7 at an adequate timing and then written onto the disk medium 15 by the read/write head 14.

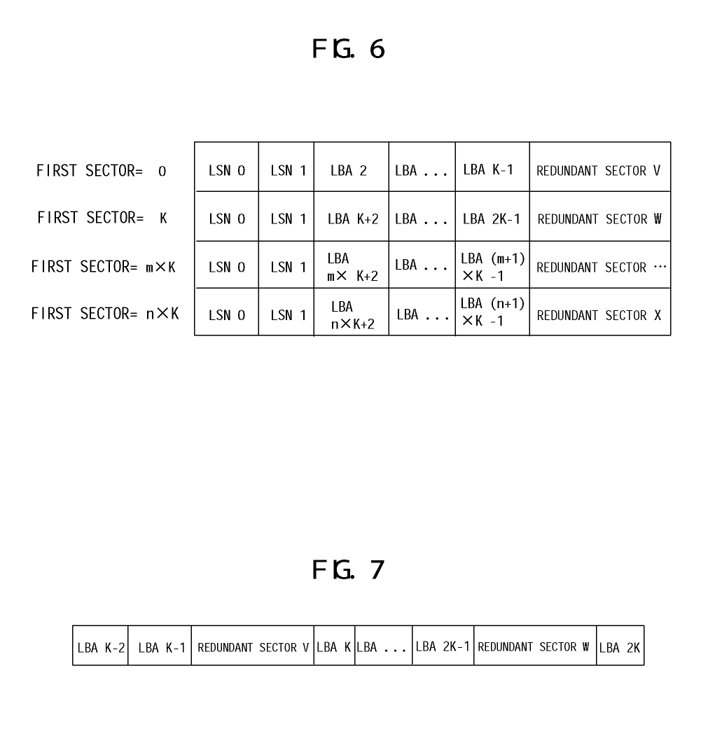

Next, the format controller and redundant data generation section in the HDD according to the present embodiment will be described. FIG. 3 is a block diagram illustrating a configuration of the format controller. FIG. 4 is a block diagram illustrating a configuration of the redundant data generation section.

As illustrated in FIG. 3, the format controller 5 includes an RLL (Run Length Limited) section 51 and an ECC section 52. The RLL section 51 performs RLL coding for data to be written onto the disk medium 15. The ECC section 52 adds ECC data to sectors of data to be written onto the disk medium 15. Although the format controller 5 has a function of applying correction processing to read out data by the added ECC data, it can transfer the data to the buffer memory 4 without applying the correction processing. The ECC section 52 may add an error detection code in place of the ECC data.

As illustrated in FIG. 4, the redundant data generation section 18 has a data memory 181 and an XOR (Exclusive OR) calculation circuit 182. The data memory 181 has a capacity corresponding to a single sector size and retains calculation result data corresponding to one sector obtained by the XOR calculation circuit 182. The XOR calculation circuit 182 XORs input data corresponding to one sector from an external device and calculation result data corresponding to one sector retained by the data memory 181 for each bit position. The result of the XOR calculation is retained by the data memory 181 as a new calculation result data. The MPU 8 can read out the calculation result data retained by the data memory 181 via the common bus 16 to set the calculation result as redundant data.

The XOR calculation circuit 182 can recover error sector data by performing XOR calculation for the redundant data and user data in each sector (first block) other than the error sector data. Further, even if the order of the sectors to be input as input data is changed, the same calculation result data can be obtained. Therefore, no matter what order all the data in a given segment are input in, the XOR calculation circuit 182 can obtain redundant data as the final calculation result data. Similarly, no matter what order the user data other than the error sector data and redundant data in the segment in which the error sector exists are input in, the XOR calculation circuit 182 can obtain recovered error sector data as the final calculation result data. Further, even with respect to a segment, like the last segment, having a smaller number of sectors than that in the other segments, the redundant data generation processing and error sector data recovery processing can be performed as in the case of the other segments by using the user data of all sectors. In the present embodiment, the redundant data generation section 18 is arranged between the read channel 6 and format controller 5, so that the data memory 181 of the redundant data generation section 18 can store user data including the ECC data in the XOR calculation. Further, the data stored in the data memory 181 as the calculation result data is sent to the buffer memory 4 via the format controller 5, so that the buffer memory 4 can receive user data for which ECC check has been made.

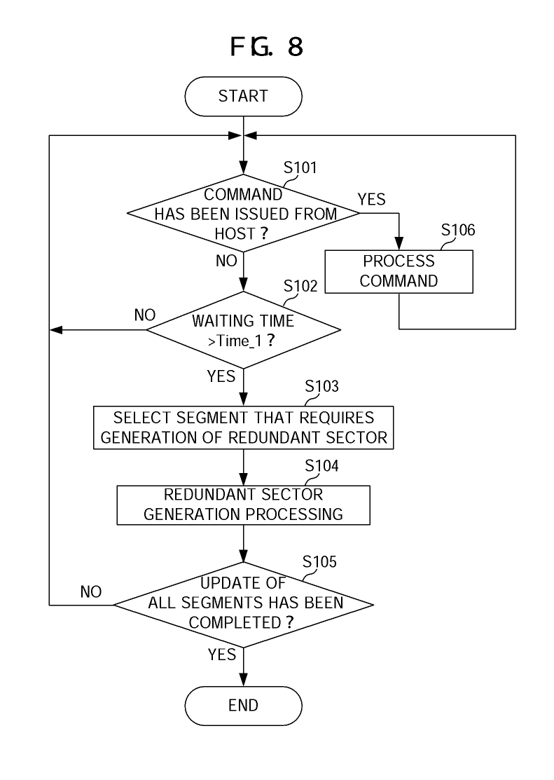

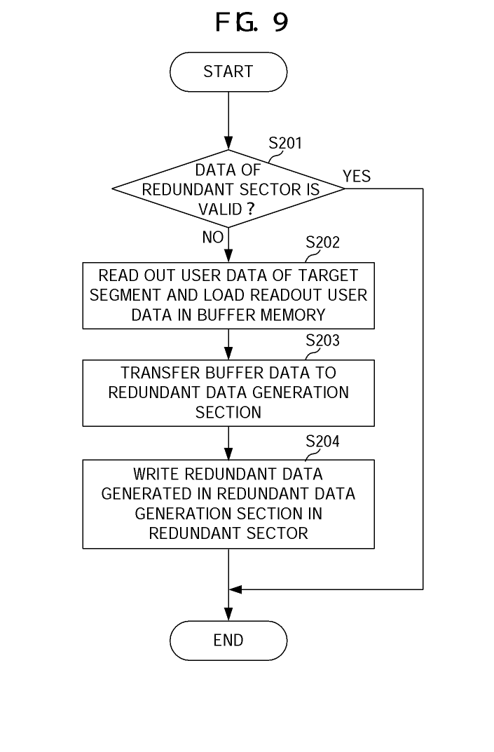

Sector allocation in the user area on the disk medium will next be described. FIG. 5 is a view illustrating an example of sector allocation in the case where a redundant sector is allocated for each track. FIGS. 6 and 7 are views illustrating examples of sector allocation in the case where a redundant sector is allocated for each predetermined number of sectors.

In the present embodiment, a redundant sector (third block) is allocated for each track or for each predetermined number of sectors (second block). First, the case where a redundant sector is allocated for each track will be described. In FIG. 5, LSN denotes a logical sector number which is a number assigned starting from the smallest LBA (Logical Block Address) in one track. The LSNs are assigned with the smallest LBA set to 0 and largest LBA set to A−1. A track of a track number K includes sectors (user data sectors) LSN 0 to LSN A−1 used for storing user data and a redundant sector K following these consecutive sectors, that is, includes a total of A+1 (because the logical sector number begins with 0).

Similarly, the number of sectors in a track K+1 represented by track number K+1 belonging to the same zone as the track K is A+1. Further, unlike the track K and track K+1, the number of sectors in a track M represented by track number M is C−1. In this track M, a redundant sector M follows consecutive user data sectors LSN 0 to LSN C−1. That is, in the case where a redundant sector is allocated for each track, the redundant sector follows a sector having the largest LSN in the track.

Next, the case where a redundant sector is allocated for each predetermined number of sectors will be described. As illustrated in FIG. 6, in the case where a redundant sector is allocated to a plurality (K+1) of sectors in which the LBA of first sector=0, a redundant sector V follows consecutive user data sectors LBA 0 to LBA K−1. Similarly, in the case where the LBA of first sector=K, a redundant sector W follows consecutive user data sectors LBA K to LBA 2K−1. Further, as illustrated in FIG. 7, in the case where LBA K−1 and LBA K are located on the same track, the redundant sector V is allocated between sectors LBA K−1 and LBA K. Further, in the case where LBA K−1 is last sector in a given track, the redundant sector is allocated before LBA K in the track on which LBA K is allocated.

Operation of the HDD according to the present embodiment will next be described. FIG. 8 is a flowchart illustrating operation of redundant data update processing. The redundant data update processing is processing for generating redundant data during a time period in which no command is issued from the higher-level device 2.

The MPU 8 of the HDD 1 determines whether a command has been issued from the higher-level device 2 as a HOST (S101).

In the case where no command has been issued from the higher-level device 2 (NO in S101), the MPU 8 determines a command waiting time (time period during which no command is issued) is larger than one second (S102).

In the case where the command waiting time is larger than one second (YES in S102), the MPU 8 refers to the disk medium 15 to select a segment (predetermined number of sectors or track) that requires generation of redundant data (S103), executes redundant data generation processing to be described later (S104), and determines whether the update of all the segments have been completed (S105). Here, the update means generation of the redundant data in the user data stored in the disk medium 15.

In the case where the update has been completed in all the segments (YES in S105), the MPU 8 ends the redundant data update processing.

On the other hand, in the case where there exists any segment in which the update has not been made (NO in S105), the MPU 8 determines once again whether a command has been issued from the higher-level device 2 (S101).

Further, in the case where the command waiting time is not more than one second in step S102 (NO in S102), the MPU 8 determines once again whether a command has been issued from the higher-level device 2 (S101).

In the case where a command has been issued from the higher-level device 2 in step S101 (S101), the MPU 8 executes processing according to the received command (S106).

According to the redundant data update processing, the redundant data can be updated during the command waiting time, i.e., while no processing is required in the HDD 1. Thus, it is possible to prevent the time required for processing a command from being increased due to generation of the redundant data.

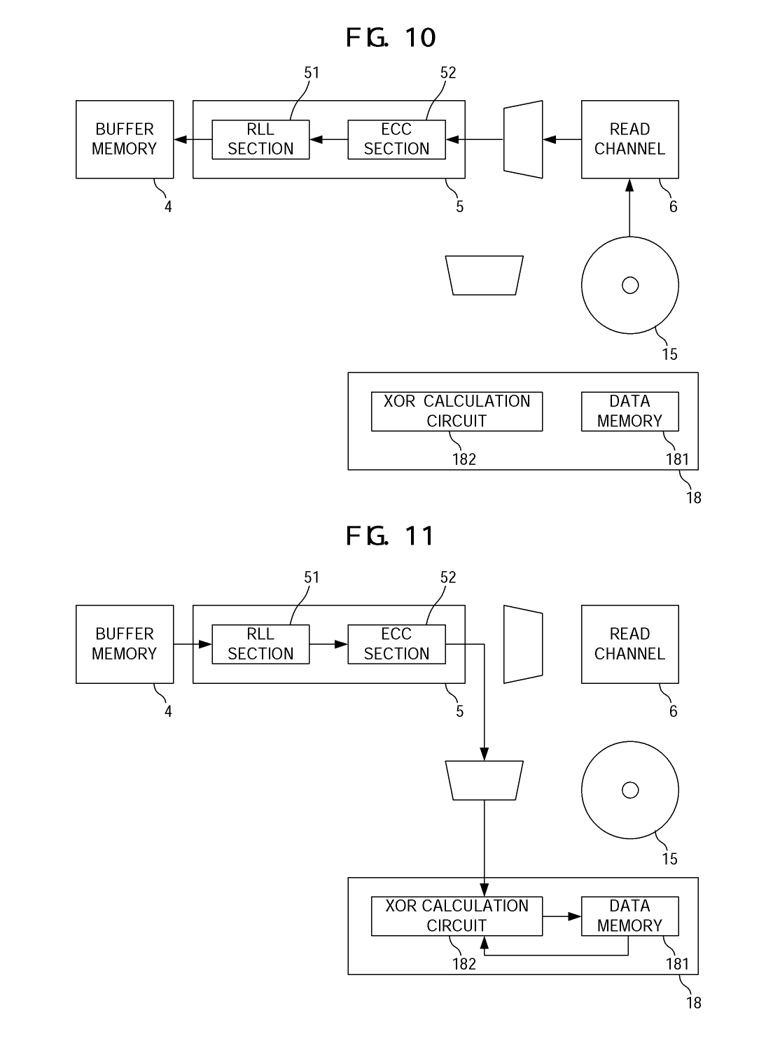

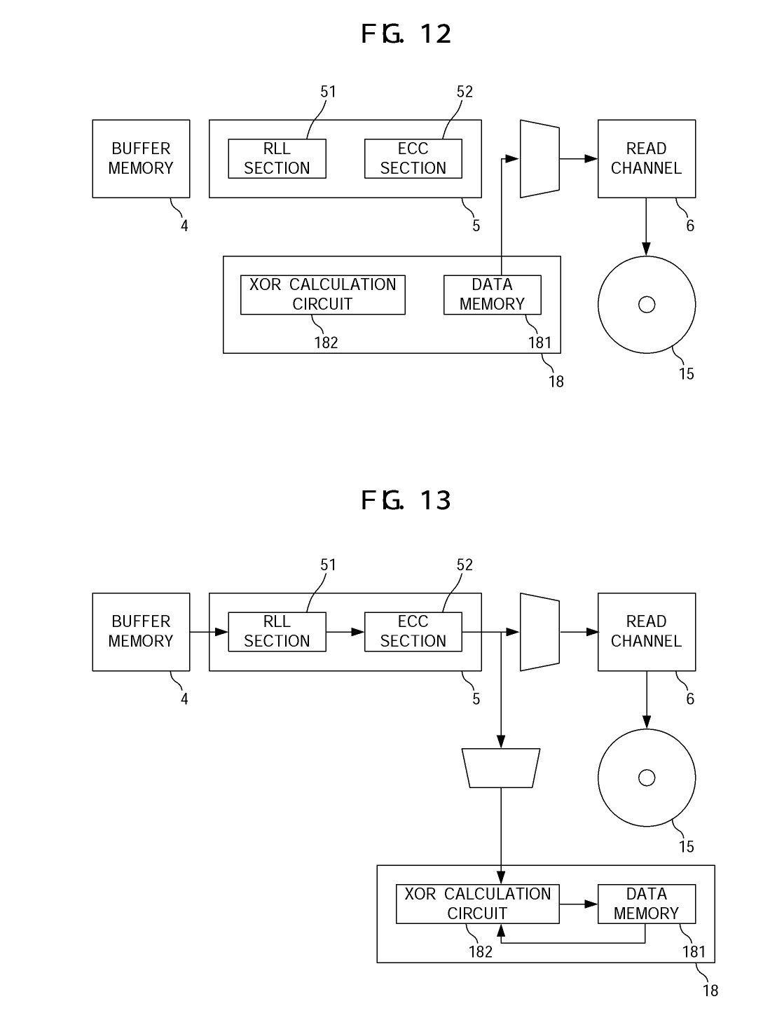

The redundant data generation processing will next be described. FIG. 9 is a flowchart illustrating operation of the redundant data generation processing. The redundant data generation processing corresponds to the processing of step S104 in FIG. 8. FIGS. 10 to 13 are views each illustrating a data path in the redundant data generation processing. Hereinafter, along the flowchart of FIG. 9, operation of the redundant data generation processing will be described using FIGS. 10 to 13. Note that the ECC has already been added to each sector of the user data in FIG. 9.

The MPU 8 refers to the user data written onto the disk medium 15 to determine whether data of the redundant sector in each segment of the user data is valid, that is, whether redundant data corresponding to the user data has been written in the redundant sector (S201).

In the case where the data of the redundant sector is not valid (NO in S201), the MPU 8 uses the read channel 6 to read the user data in which the ECC data has been added to each sector in the segment where the data of the redundant sector is not valid and uses the buffer controller 3 to load the readout user data in the buffer memory 4 via the format controller 5, as illustrated in FIG. 10 (S202).

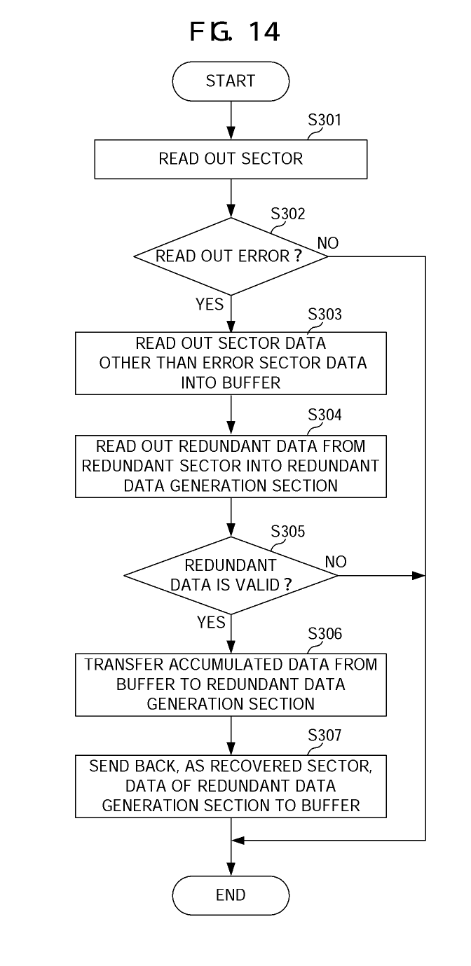

Then, as illustrated in FIG. 11, the MPU 8 transfers the user data on the buffer memory 4 to the redundant data generation section 18 via the format controller 5 (S203). Further, as illustrated in FIG. 12, the MPU 8 uses the read channel 6 to write the calculation result data on the data memory 181 as redundant data in a redundant sector in the segment of the user data input to the redundant data generation section 18 (S204).

In the case where the data of the redundant sector is valid (YES in S201), the MPU 8 ends the redundant data generation processing.

As described above, in the redundant data generation processing, all the data in a given target segment are read out so as to update the redundant data. In the case where all the data in the target segment are updated (overwritten), the update needs to be made irrespective of whether the corresponding redundant data is valid or not. In this case, as illustrated in FIG. 13, the MPU 8 inputs data to be written to the read channel 6, as well as to the redundant data generation section 18, whereby it is possible to generate the redundant data with data readout operation from the disk medium 15 omitted.

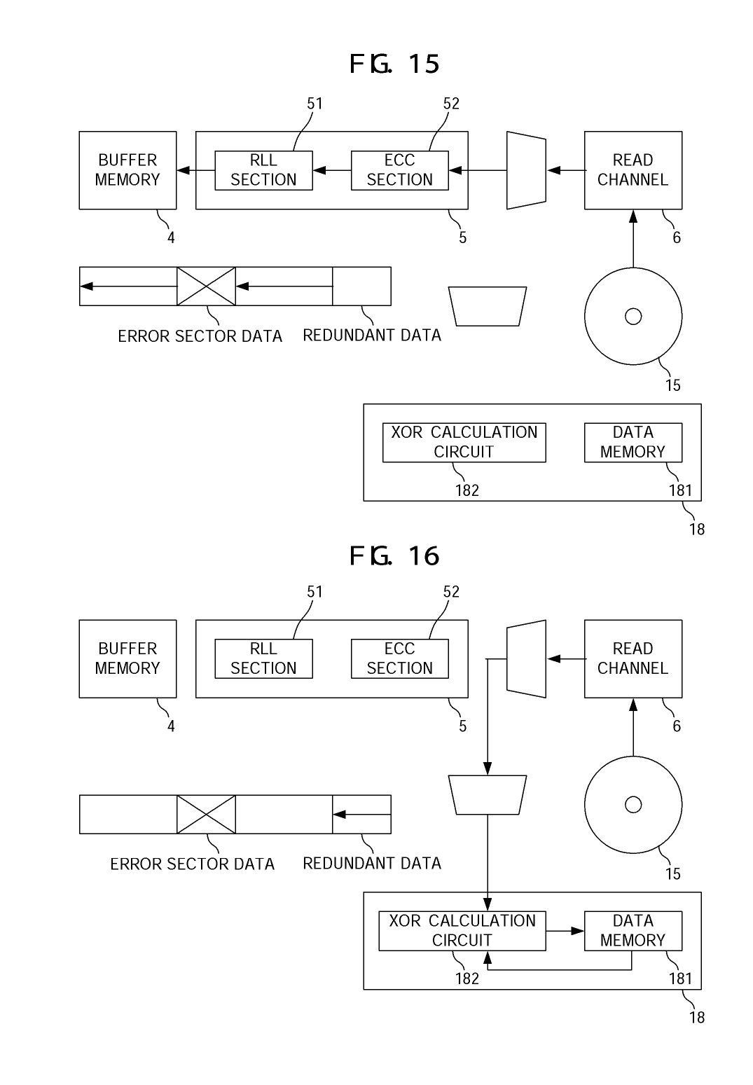

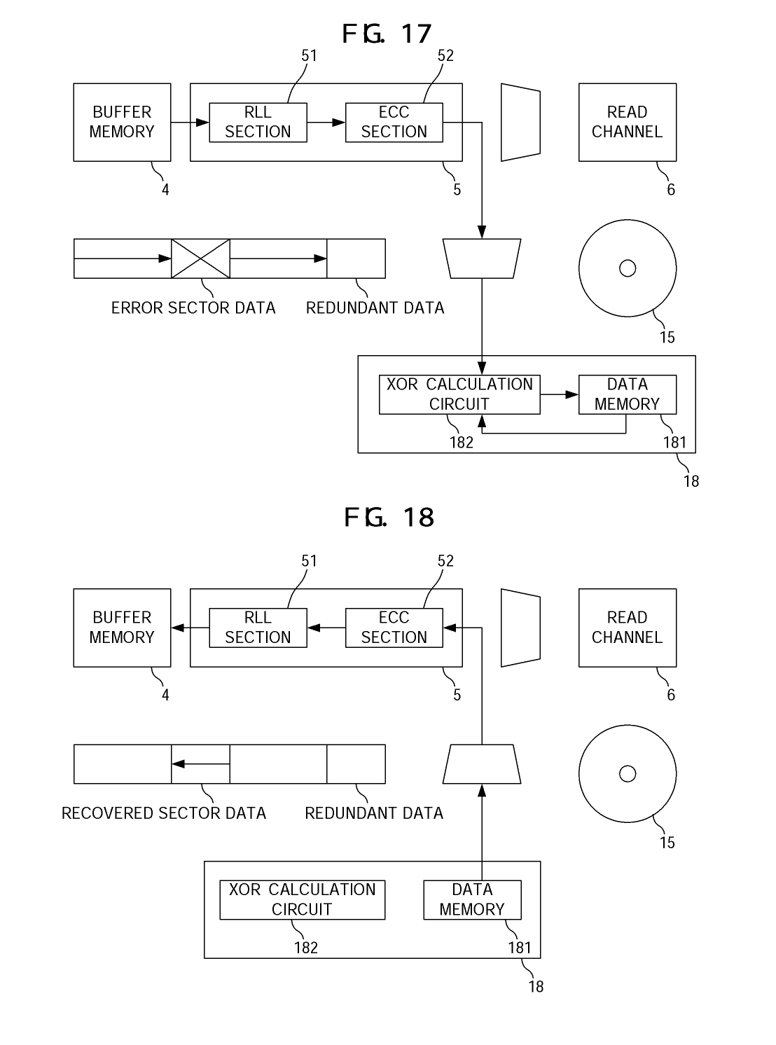

Error data recovery processing will next be described. FIG. 14 is a flowchart illustrating operation of error data recovery processing. FIGS. 15 to 18 are views each illustrating a data path in the error data recovery processing. Hereinafter, along the flowchart of FIG. 14, operation of the error data recovery processing will be described using FIGS. 15 to 18.

The MPU 8 reads out data in a given sector (S301) and determines whether the read out data is error sector data (S302).

In the case where the readout data is error sector data (YES in S302), the MPU 8 uses the read channel 6 to read out sector data other than the error sector data in a segment in which the error sector data exists and stores the read out sector data in the buffer memory 4 via the format controller 5, as illustrated in FIG. 15 (S303).

Then, as illustrated in FIG. 16, the MPU 8 uses the read channel 6 to read out the redundant data from a redundant sector corresponding to the read out segment from the disk medium 15, stores the read out redundant data in the data memory 181 (S304), and determines whether the redundant data is valid (S305).

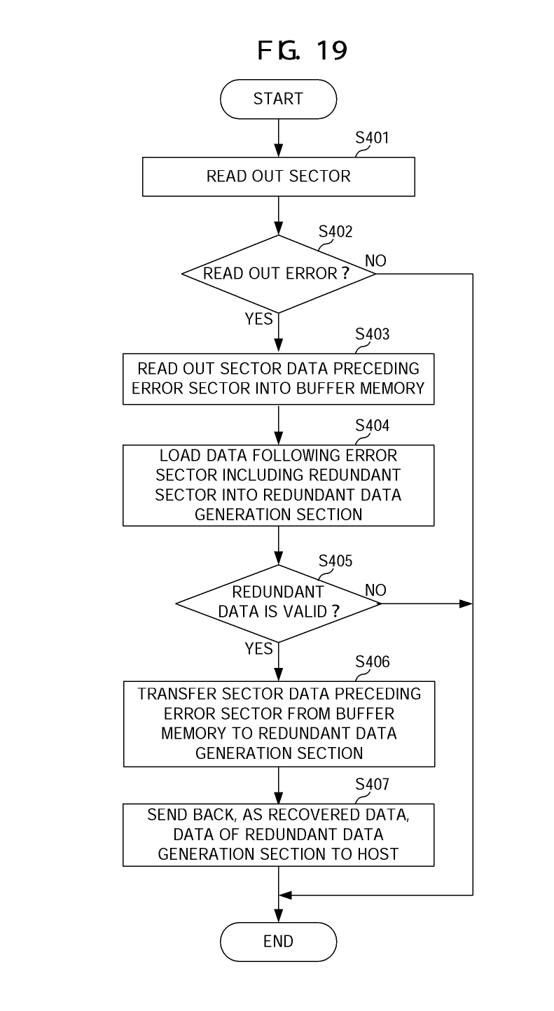

In the case where the redundant data is valid (YES in S305), the MPU 8 transfers sector data other than the error sector data from the buffer memory 4 to the redundant data generation section 18 as illustrated in FIG. 17 (S306).

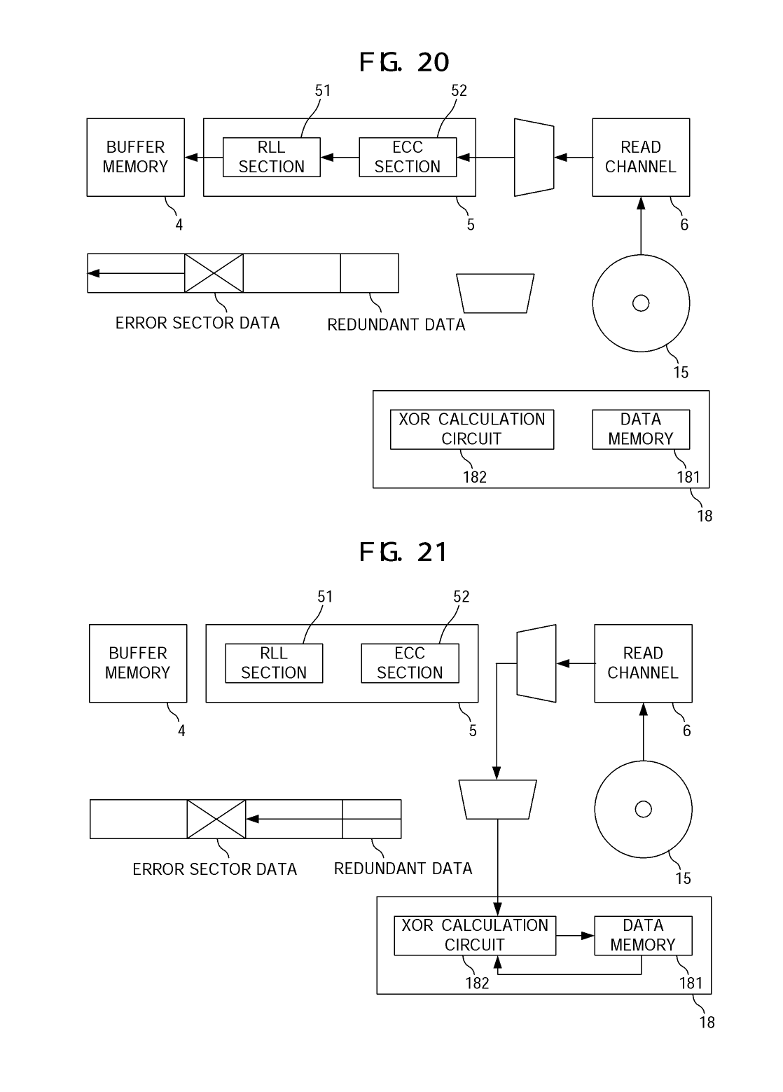

When the sector data is transferred to the redundant data generation section 18, the XOR calculation circuit 182 XORs the sector data and redundant data stored in the data memory 181 to obtain calculation result data. The MPU 8 sends back, as recovered data corresponding to the error sector data, the obtained calculation result data to the buffer memory 4 via the format controller 5, as illustrated in FIG. 18 (S307).

In the case where the redundant data is not valid (NO in S305), the MPU 8 ends the error data recovery processing.

In the case where the read out data is not error sector data (NO in S302), the MPU 8 ends the error data recovery processing.

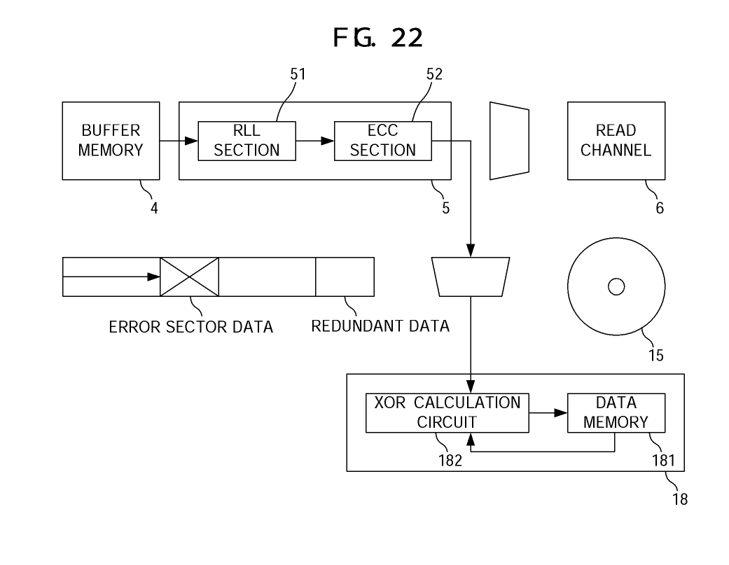

As described above, in the error data recovery processing, data other than the error sector data is stored in the buffer memory 4, and the stored data and redundant data are XORed to thereby recover the error sector data. Note that the error data recovery processing may be performed such that only the data preceding the error sector is stored in the buffer memory 4, as described below. FIG. 19 is a flowchart illustrating operation of the error data recovery processing in the case where only the data preceding the error sector is stored in the buffer memory. FIGS. 20 to 23 are views each illustrating a data path in this error data recovery processing. Hereinafter, along the flowchart of FIG. 19, operation of the error data recovery processing in the case where only the data preceding the error sector is stored in the buffer memory will be described using FIG. 18 and FIGS. 20 to 22.

The MPU 8 reads out data in a given sector (S401) and determines whether the readout data is error sector data (S402).

In the case where the readout data is error sector data (YES in S402), the MPU 8 uses the read channel 6 to read out sector data preceding the error sector in the segment where the error sector data exists from the disk medium 15 and stores the readout sector data in the buffer memory 4 via the format controller 5, as illustrated in FIG. 20 (S403).

Then, as illustrated in FIG. 21, the MPU 8 uses the read channel 6 to read out sector data following the error sector and redundant data from the disk medium 15, stores the readout data in the data memory 181 (S404) and determines whether the stored redundant data is valid (S405).

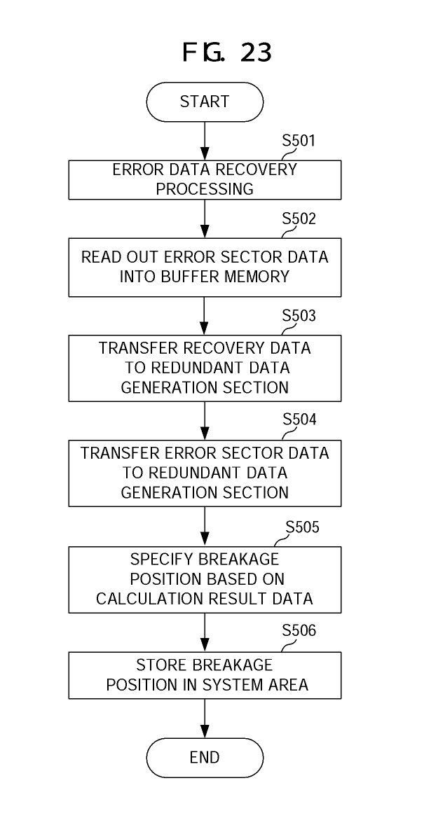

In the case where the redundant data is valid (YES in S405), the MPU 8 transfers the sector data preceding the error sector from the buffer memory 4 to the redundant data generation section 18, as illustrated in FIG. 22 (S406).

When the sector data preceding the error sector is transferred to the redundant data generation section 18, the XOR calculation circuit 182 XORs the sector data following the error sector and redundant data stored in the data memory 181 to obtain calculation result data. The MPU 8 sends back, as recovered data corresponding to the error sector data, the obtained calculation result data to the buffer memory 4 via the format controller 5, as illustrated in FIG. 18 (S407).

In the case where the redundant data is not valid (NO in S405), the MPU 8 ends the error data recovery processing.

In the case where the read out data is not error sector data (NO in S402), the MPU 8 ends the error data recovery processing.

As described above, when the error data recovery processing is executed by reading only the sector data preceding the error sector into the buffer memory 4, it is possible to reduce the required buffering capacity of the buffer memory 4 in the error data recovery processing.

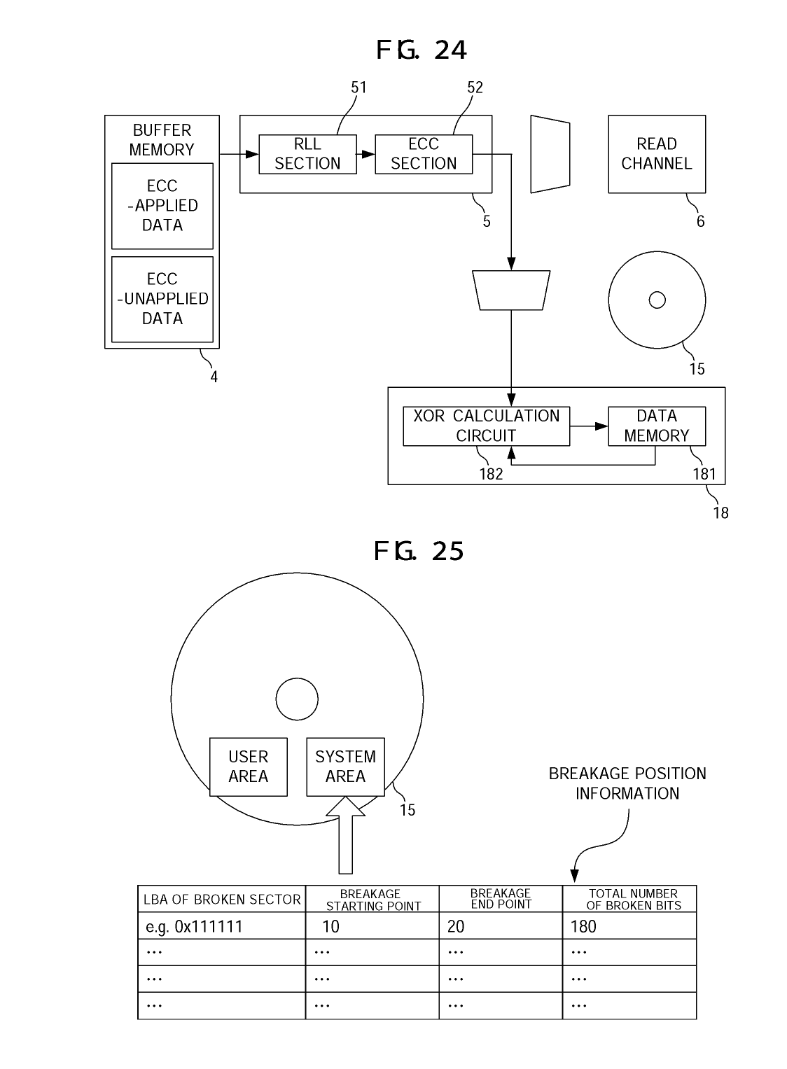

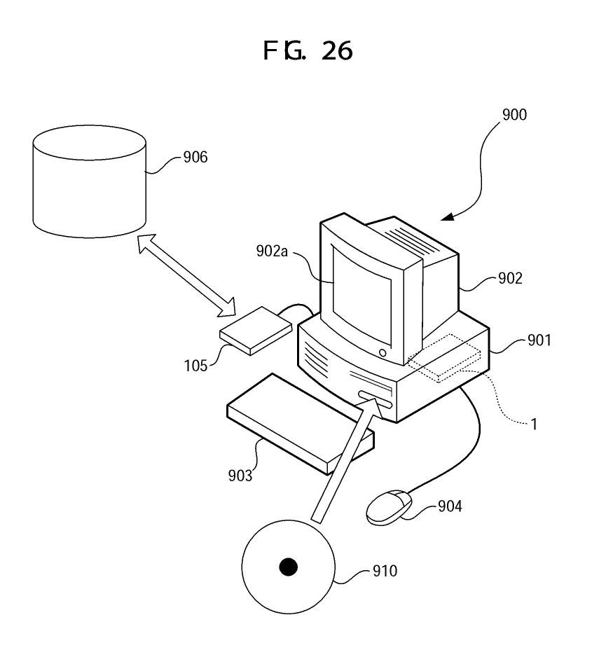

Further, the HDD 1 according to the present embodiment can specify data breakage position by performing XOR calculation using the error sector data and recovered data. FIG. 23 is a flowchart illustrating operation of breakage position specification processing. FIG. 24 is a view illustrating a data path in the breakage position specification processing. FIG. 25 is a view illustrating breakage position information. Hereinafter, along the flowchart of FIG. 23, operation of the breakage position specification will be described using FIGS. 23 and 24.

The MPU 8 executes the abovementioned error data recovery processing (S501) and reads out error sector data into the buffer memory 4 via the format controller 5 (S502). At this time, the format controller 5 does not apply ECC correction to the error sector data.

Then, as illustrated in FIG. 24, the MPU 8 transfers data corresponding to the error sector data recovered by the error data recovery processing to the redundant data generation section 18 (S503) and transfers the error sector data to the redundant data generation section 18 (S504). The MPU 8 specifies data breakage position based on calculation result data obtained by XOR calculation using the recovered data and error sector data (S505). In this calculation result data, a position at which values differ between the two data indicates a bit “1” and position at which values are the same between the two indicates a bit “0”, so that it is possible to specify the position at which data is broken.

Then, as illustrated in FIG. 25, the MPU 8 records the specified data breakage position in the system area of the disk medium 15 as breakage position information (S506). The breakage position information indicates an association among the LBA of a broken sector, breakage starting position and breakage end position in the broken sector, and total number of broken bits.

As described above, by generating redundant sector data for user data including ECC data, it is possible to record the statistical data concerning the data breakage position in the system area of the HDD 1. The stored statistical data can be used for managing quality of the HDD 1. Further, according to the present invention, it is possible to enhance error recovery capability.

Although the XOR calculation is used for performing the redundant sector data generation processing and error sector data recovery processing using the redundant sector data in the present embodiment, other calculations may be employed as far as they are calculation methods in which the same calculation result can be obtained even if the order of a plurality of sectors to be input as input data is changed. Further, although the input data and calculation result data are treated in units of sectors, they may be treated in units of other data lengths such as a byte and word.

The present invention can be embodied in various forms, without departing from the spirit or the main feature. Therefore, the aforementioned embodiment is merely illustrative of the invention in every aspect, and not imitative of the same. The scope of the present invention is defined by the appended claims, and is not restricted by the description herein set forth. Further, various changes and modifications to be made within the scope of the appended claims and equivalents thereof are to fall within the scope of the present invention.

The present invention can be applied to a computer system as the higher-level device 2 to be described later. FIG. 26 is a view illustrating an example of a computer system to which the present invention can be applied. A computer system 900 illustrated in FIG. 26 includes a main body 901 incorporating a CPU, HDD 1, and the like, a display 902 that displays an image according to an instruction issued from the main body 901, a keyboard 903 for a user to input various information to the computer system 900, a mouse 904 for a user to specify a given position on a display screen 902a on the display 902, and a communication unit 905 that accesses an external database to download a program stored in another computer system. The communication unit 905 may be a network communication card or a modem.

Further, it is possible to provide a program that allows the MPU 8 of the HDD 1 or a computer system to execute the above steps as a stored data processing program. By storing the above program in a computer system-readable storage medium, it is possible to allow the computer system to execute the program. The program read by the computer system can be stored in the non-volatile memory 10 of the HDD 1 via the computer system. The program that executes the above steps is stored in a portable recording medium such as a disk 910 or downloaded from a recording medium 906 of another computer system by the communication unit 905. A stored data processing program (stored data processing software) imparting at least a data recovery function to the computer system 900 is input to the computer system 900 and compiled. The program allows the computer system 900 to operate as a recovery system having a recovery function. Further, the program may be stored in a computer-readable recording medium such as a disk 910. The medium that can be read by the computer system 900 includes: an internal storage device mounted in a computer, such as ROM or RAM, a portable storage medium such as the disk 910, a flexible disk, a DVD disk, a magneto-optical disk, or an IC card; a database that holds computer program; another computer system and database thereof; and various types of recording media accessed by a computer system connected to the media via a communication means like the communication unit 105.

According to the present embodiment, it is possible to effectively calculate the importance of a document considering the influence of parameters concerning the document.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A stored data processing apparatus for use in a storage apparatus that performs at least write processing for a storage medium on which data is allocated in units of a first block having a predetermined data length, comprising:
an error correction code addition section that adds an error correction code to data written onto the storage medium for each first block;
a calculation section that performs calculation for each bit position using data of all the first blocks in a second block and outputs a result of the calculation as calculation data, the second block being constituted by a plurality of the first blocks each including the error correction code added by the error correction code addition section and specified as an update target; and
a write section that writes the calculation data output from the calculation section in a third block associated with the second block as the update target.

2. The stored data processing apparatus according to claim 1, further comprising:
a readout section that reads normal data of all the error correction code added blocks other than an error block from the second block as the readout target, and redundant data which is data of a third block corresponding to the second block as the readout target, the error block being the error correction code added block determined to be error data in the case where data read out in readout operation of the second block as a readout target from an error correction code added block which is the first block to which the error correction code has been added is determined to be error data, wherein
the calculation section further performs calculation for each bit position using the normal data and redundant data and outputs a result of the calculation as data of the error block.

3. The stored data processing apparatus according to claim 2, further comprising:
an error position specification section that compares for each bit position the error block readout by the readout section and calculation result obtained by the calculation section and specifies a position on the storage medium at which values differ between the error block and calculation result as an error position.

4. The stored data processing apparatus according to claim 3, further comprising an error position recording section that records the error position specified by the error position specification section.

5. The stored data processing apparatus according to claim 4, wherein
the error correction code added block is a sector, and
the error position recording section records the error position as statistical data using the address of a sector including the error position and byte position corresponding to the error position.

6. The stored data processing apparatus according to claim 1, wherein
the calculation performed by the calculation section is a calculation in which the same calculation result can be obtained even if the order of the calculation is changed.

7. The stored data processing apparatus according to claim 5, wherein
the calculation performed by the calculation section is exclusive OR.

8. A storage apparatus that performs at least write processing for a storage medium on which data is allocated in units of a first block having a predetermined data length, comprising:
an error correction code addition section that adds an error correction code to data written onto the storage medium for each first block;
a calculation section that performs calculation for each bit position using data of all the first blocks in a second block and outputs a result of the calculation as calculation data, the second block being constituted by a plurality of the first blocks each including the error correction code added by the error correction code addition section and specified as an update target; and
a write section that writes the calculation data output from the calculation section in a third block associated with the second block as the update target.

9. The storage apparatus according to claim 8, further comprising:
a readout section that reads normal data of all the error correction code added blocks other than an error block from the second block as the readout target, and redundant data which is data of a third block corresponding to the second block as the readout target, the error block being the error correction code added block determined to be error data in the case where data read out in readout operation of the second block as a readout target from an error correction code added block which is the first block to which the error correction code has been added is determined to be error data, wherein
the calculation section further performs calculation for each bit position using the normal data and redundant data and outputs a result of the calculation as data of the error block.

10. The storage apparatus according to claim 9, further comprising:
an error position specification section that compares for each bit position the error block readout by the readout section and calculation result obtained by the calculation section and specifies a position on the storage medium at which values differ between the error block and calculation result as an error position.

11. The storage apparatus according to claim 10, further comprising an error position recording section that records the error position specified by the error position specification section.

12. The storage apparatus according to claim 11, wherein
the error correction code added block is a sector, and
the error position recording section records the error position as statistical data using the address of a sector including the error position and byte position corresponding to the error position.

13. A computer readable storage medium storing a stored data processing program allowing a stored data processing program for use in a storage apparatus that performs at least write processing for a storage medium on which data is allocated in units of a first block having a predetermined data length to be read by a computer, that allows the computer to execute a process comprising:
adding an error correction code to data written onto the storage medium for each first block;
performing calculation for each bit position using data of all the first blocks in a second block, the second block being constituted by a plurality of the first blocks each including the error correction code added in the adding and specified as an update target;
outputting a result of the calculation by the performing of calculation as calculation data; and
writing the calculation data output from the outputting in a third block associated with the second block as the update target.

14. The computer readable storage medium according to claim 13, wherein the process further comprises:
reading normal data of all the error correction code added blocks other than an error block from the second block as the readout target, and redundant data which is data of a third block corresponding to the second block as the readout target, the error block being the error correction code added block determined to be error data in the case where data read out in readout operation of the second block as a readout target from an error correction code added block which is the first block to which the error correction code has been added is determined to be error data, and
the performing of calculation performs calculation for each bit position using the normal data and redundant data,
the outputting outputs a result of the calculation as data of the error block.

15. The computer readable storage medium according to claim 14, wherein the process further comprises:
comparing for each bit position the error block readout by the reading and calculation result obtained by the outputting; and
specifying a position on the storage medium at which values differ between the error block and calculation result as an error position.

16. The computer readable storage medium according to claim 15, wherein the process further comprises:
recording the error position specified by the specifying.

17. A stored data processing method for use in a storage apparatus that performs at least write processing for a storage medium on which data is allocated in units of a first block having a predetermined data length, the method comprising:
adding an error correction code to data written onto the storage medium for each first block;
performing calculation for each bit position using data of all the first blocks in a second block, the second block being constituted by a plurality of the first blocks each including the error correction code added in the adding and specified as an update target;
outputting a result of the calculation by the performing of calculation as calculation data; and
writing the calculation data output from the outputting in a third block associated with the second block as the update target.

18. The stored data processing method according to claim 17, further comprising:
reading normal data of all the error correction code added blocks other than an error block from the second block as the readout target, and redundant data which is data of a third block corresponding to the second block as the readout target, the error block being the error correction code added block determined to be error data in the case where data read out in readout operation of the second block as a readout target from an error correction code added block which is the first block to which the error correction code has been added is determined to be error data;
wherein
the performing of calculation further performs calculation for each bit position using the normal data and redundant data,
the outputting a result of the calculation by the performing of calculation for each bit position as data of the error block.

19. The stored data processing method according to claim 18, further comprising:
comparing for each bit position the error block readout by the reading and calculation result obtained by the performing of calculation,
specifying a position on the storage medium at which values differ between the error block and calculation result as an error position.

20. The stored data processing method according to claim 19, further comprising:
recording the error position specified by the specifying.
